(19) United States
(12) Patent Application Publication
(10) Pub. No.: US 2004/0192043 A1
(43) Pub. Date: Sep. 30, 2004

(54) Surface treatment method for a compound semiconductor layer and method of fabrication of a semiconductor device

(75) Inventors: Takehiko Makita, Tokyo (JP); Katsuaki Kaifu, Tokyo (JP)

Correspondence Address: VENABLE, BAETJER, HOWARD AND CIVILETTI, LLP, P.O. BOX 34385, WASHINGTON, DC, 20043-9998, US

(73) Assignee: Oki Electric Industry Co., Ltd., Tokyo (JP)

(21) Appl. No.: 10/717,547

(22) Filed: Nov. 21, 2003

(30) Foreign Application Priority Data
Nov. 22, 2002 (JP) 2002-339699
Nov. 7, 2003 (JP) 2003-378076

(51) Int. Cl. H01L 21/302; H01L 21/461

(52) U.S. Cl. 438/689

(57) ABSTRACT

In a semiconductor fabrication process, a compound semiconductor layer including nitrogen is treated with nitrogen plasma to recover from nitrogen vacancies in its surface. For example, in the fabrication of a compound semiconductor transistor, a first compound semiconductor layer including nitrogen and a second compound semiconductor layer differing in composition from the first compound semiconductor layer are deposited, source and drain electrodes are formed on the second compound semiconductor layer, and part of the second compound semiconductor layer between the source and drain electrodes is removed by dry etching to expose the first compound semiconductor layer. The first compound semiconductor layer is annealed to remove adsorbed dry etching gas species; then its exposed surface is treated with nitrogen plasma to recover from nitrogen vacancies left by the dry etching and annealing processes. A gate electrode formed on the exposed surface of the first compound semiconductor layer exhibits a desirable Schottky characteristic.

### BACKGROUND OF THE INVENTION

1. Field of the Invention

The present invention relates to a method of fabrication of a semiconductor device incorporating a compound semiconductor layer having nitrogen as a constituent element, and more particularly to a method of treating the surface of this layer to decrease nitrogen vacancies.

2. Description of the Related Art

High electron mobility transistors (HEMTs) in which a quantized two-dimensional electron gas (2DEG) is created at a heterojunction interface formed by different compound semiconductor layers combine high speed and excellent high-frequency operating characteristics with other desirable characteristics, such as low noise. At present HEMTs are used in high-output devices such as microwave devices. Much current research is directed toward gallium nitride HEMTs, in which the heterojunction is formed by a gallium nitride (GaN) channel layer and an n-type aluminum gallium nitride (Al×Ga₁−N, 0<×<) electron supply layer. These devices, which exhibit superlative electrical characteristics, are referred to as AlGaN/GaN HEMTs, or simply as GaN HEMTs.

A particular type of AlGaN/GaN HEMT has a recessed structure in which the gate electrode is deposited on the AlGaN layer, which overlies the GaN channel layer, but the source and drain electrodes are deposited on a further n-type GaN layer overlying the n-type AlGaN layer. Recessed HEMTs are conventionally fabricated by, for example, the process illustrated in FIGS. 8A to 8C.

Referring to FIG. 8A, the recessed HEMT may be formed on a sapphire substrate 12. A GaN buffer layer 16, a GaN channel layer 20, an n-type Al_{0.2}Ga_{0.8}N electron supply layer 22, and an n-type GaN layer 24 are successively deposited on the substrate 12, forming a multilayer structure 40 in which a two-dimensional electron gas 23 is generated in the surface of the GaN channel layer 20. The sapphire substrate 12, GaN buffer layer 16, and GaN channel layer 20 constitute a base structure 21. The n-type Al_{0.2}Ga_{0.8}N electron supply layer 22 and n-type GaN layer 24 constitute an n-type compound semiconductor multilayer 25. A source electrode 26 and drain electrode 28 are formed on the n-GaN layer 24.

Part of the n-GaN layer 24 is then removed by inductively coupled plasma reactive-ion etching (ICP-RIE), using a chlorine-based etching gas such as boron trichloride (BCl₃), to expose the surface of the Al_{0.2}Ga_{0.8}N electron supply layer 22 (FIG. 8B). The remaining parts of the n-GaN layer function as a contact layer 32 for the source and drain electrodes. After an annealing step, a gate electrode 38 is formed by depositing nickel (Ni), for example, on the exposed surface of the Al_{0.2}Ga_{0.8}N electron supply layer 22, completing the structure of a recessed HEMT 50 (FIG. 8C).

The current-voltage characteristic (I-V characteristic) of the gate electrode 38 of the recessed HEMT 50 is shown in FIG. 9. The horizontal axis indicates voltage in volts (V), and the vertical axis indicates current density in amperes per square centimeter (A/cm²). The I-V characteristic is measured by applying different voltages between the gate electrode 38 and the drain electrode 28 (or source electrode 26) and measuring the resulting current flow. The measured characteristic is linear, that is, the current density is proportional to the applied voltage, indicating that both the gate and drain electrodes (or gate and source electrodes) are in ohmic contact with the underlying compound semiconductor layers 22, 32. To function as a control electrode, however, the gate electrode of an HEMT must form a Schottky junction with the electron supply layer 22. If the gate electrode forms an ohmic contact, gate current leakage occurs and the recessed HEMT does not operate properly. The reason for the ohmic characteristic is thought to be that damage to the n-AlGaN surface caused by dry etching (e.g., by ICP-RIE) prevents the formation of a Schottky barrier.

Therefore, there is a need for a method of treating the surface to eliminate or at least reduce the damage caused by dry etching.

The effects of treating the surface of an n-type GaN compound semiconductor layer with hydrogen plasma and nitrogen plasma have been reported by T. Hashizume and R. Nagasaki in ‘Discrete surface related to nitrogen-vacancy defect on plasma-treated GaN surfaces’, Applied Physics Letters, Vol. 80, No. 24, pp. 4564-4566 (2002). After the plasma treatment, silicon nitride (SiNₓ). and aluminum (Al) were deposited to form an Al/SiNₓ/n-GaN metal-insulator-semiconductor (MIS) structure. Before the plasma treatment, the surface of the n-GaN layer was free of damage. Hydrogen plasma caused nitrogen to be desorbed from the surface in the form of an NHₓ, creating a donor level due to nitrogen vacancies. Nitrogen plasma treatment did not create nitrogen vacancies.

This suggests that the surface of a nitrogen-containing compound semiconductor layer can be treated with nitrogen plasma without causing nitrogen-vacancy damage, but there remains the problem of recovering from surface damage that has already been caused by dry etching.

### SUMMARY OF THE INVENTION

In the course of research directed toward methods of recovering from dry etching damage to compound semiconductors, the present inventors reached the conclusion that for the of an n-type AlGaN layer, a nitrogen plasma. surface treatment process provides a solution. A basic aspect of the present invention is the use of nitrogen plasma surface treatment to recover from damage due to nitrogen vacancies arising at or near the surface of a compound semiconductor layer including nitrogen.

The nitrogen plasma surface treatment process can be carried out with etching equipment, in which case the damaged surface of the compound semiconductor layer is slightly etched. Alternatively, the surface of the compound semiconductor layer may simply be exposed to nitrogen plasma, without etching, to recover from nitrogen vacancy damage.

In a further aspect of the invention, the compound semiconductor layer is a multilayer comprising a first compound semiconductor layer including nitrogen and a second compound semiconductor layer formed on and differing in composition from the first compound semiconductor layer. Part of the second compound semiconductor layer is removed by etching to expose the first compound semiconductor layer. Recovery from damage due to nitrogen vacancies arising in the surface of the first compound semiconductor layer is then effected by treatment with nitrogen plasma.

Both aspects of the invention recover from damage due to nitrogen vacancies arising in the surface of the compound semiconductor layer including nitrogen, or at least reduce the damage, leaving a surface structure with good electrical characteristics.

In the method of fabrication of a semiconductor device of the present invention, the following steps are performed in the following order: a compound semiconductor multilayer, comprising a first compound semiconductor layer including nitrogen and a second compound semiconductor layer formed on and differing in composition from the first compound semiconductor layer, is formed on a substrate; a first main electrode and a second main electrode, which are spaced apart each other by a certain distance, are formed on the second compound semiconductor layer; an area of the second compound semiconductor layer between the first main electrode and the second main electrode is removed by dry etching to expose the surface of the first compound semiconductor layer; the partially exposed first compound semiconductor layer is annealed; at least part of the exposed surface of the first compound semiconductor layer is treated by exposure to nitrogen plasma, or by etching with nitrogen plasma; a gate electrode is formed on the treated part of the surface of the first compound semiconductor layer.

The invented method of fabrication of a semiconductor device eliminates or at least reduces damage due to nitrogen vacancies arising in the surface of the first compound semiconductor layer from dry etching, thereby creating a surface structure having good electrical characteristics.

### BRIEF DESCRIPTION OF THE DRAWINGS

In the attached drawings:

FIGS. 1A, 1B, 1C, 1D, 2A, 2B, 2C, 3A, 3B, and 3C are sectional drawings illustrating steps in a first embodiment of the invention;

FIG. 4 is a graph illustrating x-ray photoelectron spectra of an n-AlGaN surface before and after annealing in the first embodiment;

FIGS. 5A, 5B, and 5C are atomic force micrographs of the n-AlGaN surface before and after annealing in the first embodiment;

FIGS. 6A and 6B are graphs illustrating the gate-to-drain current-voltage characteristic of a recessed HEMT formed in the first embodiment;

FIG. 7 is a graph illustrating x-ray photoelectron spectra of the n-AlGaN surface before and after rinsing in a second embodiment of the invention;

FIGS. 8A, 8B, and 8C are sectional drawings illustrating steps in a conventional recessed HEMT fabrication process; and

FIG. 9 is a graph illustrating the gate-to-drain current-voltage characteristic of a recessed HEMT fabricated by the conventional process.

### DETAILED DESCRIPTION OF THE INVENTION

Embodiments of the invention will now be described with reference to the drawings. Each drawing is a cross-sectional view a semiconductor device illustrating a step in an example of the invented fabrication method. The drawings show the shapes, sizes, and layout of constituent elements schematically, and are intended to provide an aid to understanding of the invention but not to limit the scope of the invention. Hatching of some constituent elements is omitted to make the drawings easier to comprehend. Although specific materials, processing conditions, and the like may be referred to in the description below, these materials and conditions amount only to preferred examples, to which the invention is not restricted. Like elements are indicated by like reference characters in the drawings, and redundant descriptions may be omitted.

### First Embodiment

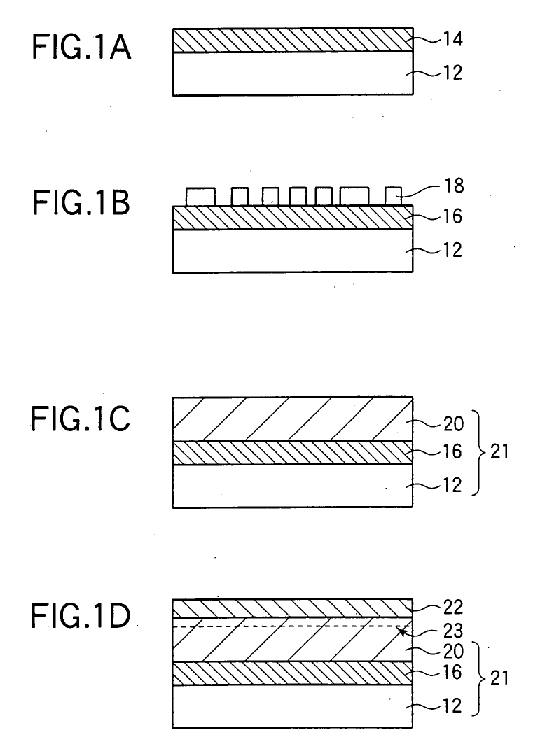

The method of fabrication of a semiconductor device in the first embodiment of the present invention will be described with reference to FIGS. 1A through 6B. In the first embodiment, a method of fabrication of a GaN HEMT will be described as an example. The layers described below are deposited by using standard metal-organic chemical vapor deposition (MOCVD) techniques. Trimethyl-gallium (Ga(CH₃)₃) and trimethyl-aluminum (Al(CH₃) ₃), which are metal organic compounds having an alkyl as a constituent element, are used as supply sources for group III materials, and ammonia (NH₃) is used as a supply source for a group V element. Since the specific methods of crystal growth for each layer are well known, detailed descriptions will be omitted when not specially needed.

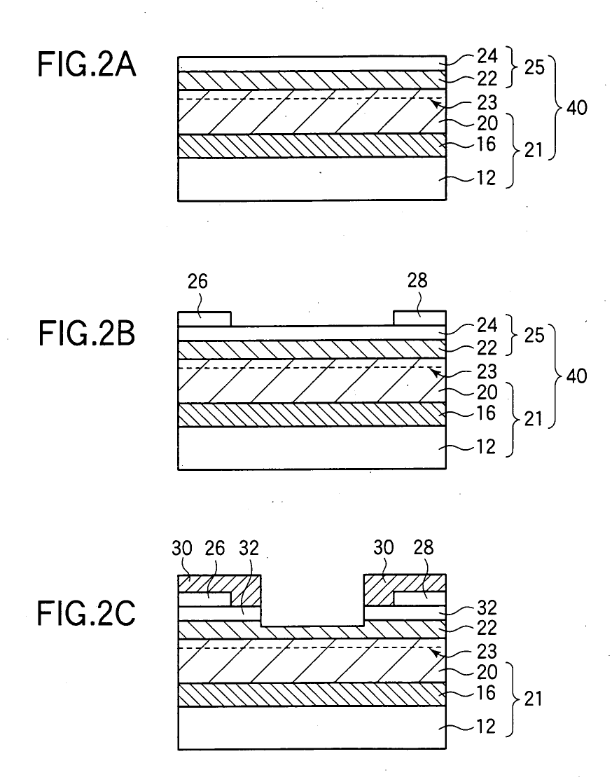

The first series of steps will be described with reference to FIGS. 1A through 2C. Referring to FIG. 1A, a c-axis -oriented sapphire (A1₂O₃) substrate is used. A GaN layer 14 is deposited on the sapphire substrate 12 by MOCVD at a temperature in the range between 400° C. and 600° C. in which GaN is amorphous (temperatures in this range will be denoted Tₐ° C. below). The amorphous GaN layer 14 has a thickness of, for example, ten to fifty nanometers (10 nm to 50 nm), and has a flat surface.

The temperature of the sapphire substrate 12 is then raised to between 950° C. and 1150° C., for example, (temperatures in this range will be referred to as growth temperatures and denoted T₁° C. below), changing the amorphous GaN layer 14 to a crystalline GaN buffer layer 16. More specifically, as the temperature rises, the amorphous GaN layer 14 acquires a columnar structure growing from many seed crystals on the substrate side. Although the amorphous GaN layer 14 is simultaneously being etched by the reactant gas during the transition to the columnar structure, the GaN buffer layer 16 can be formed uniformly on the substrate surface by increasing the rate of change to the columnar structure. The rise of the temperature to the growth temperature T₁° C. must take place during a time long enough for the amorphous GaN layer 14 to change from a low-temperature buffer layer to a GaN buffer layer 16 having a columnar structure, but the time must be short enough that the amorphous GaN layer 14 is not etched away by the reactant gas and remains present until the growth temperature T₁° C. is reached.

If the amorphous GaN layer 14 is deposited to a thickness of 20 nm at a temperature Ta of 500° C., and the temperature rise that changes the amorphous GaN layer 14 to a GaN buffer layer 16 ends at a growth temperature T₁ of 1040° C., for example, the optimum value of the temperature rise time is about seven minutes. The optimum temperature rise time is not limited to this value, but depends on the type of low-temperature buffer layer (GaN or AlN), its film thickness, the gas species at the time of deposition, the gas flow rate, and the specifications of the MOCVD equipment. The growth temperature T₁° C., is preferably between 950° C. and 1150° C., and more preferably between 1000° C. and 1100° C. A GaN buffer layer 16 having a good crystalline structure can thereby be deposited.

After the growth temperature T₁° C. has been reached, GaN growth seeds 18 are deposited by MOCVD on the GaN buffer layer 16 at a uniform high density (FIG. 1B).

Growth now resumes at a temperature lower than the growth temperature T₁° C. Many GaN grain boundaries at which the crystalline orientation shifts slightly are formed, the GaN growth seeds 18 serving as seed.crystals. As a result of repeated coalescence and dislocation of adjacent crystal grains, an undoped GaN channel layer 20 having a good monocrystalline structure with a uniform crystalline orientation and comparatively few defects is formed with a thickness between, for example, 2000 nm and 5000 nm (FIG. 1C). To obtain a GaN channel layer 20 having a good crystalline structure with few defects, the GaN channel layer 20 should be at least 100 nm thick. The sapphire substrate 12, the GaN buffer layer 16, and the GaN channel layer 20 constitute a base structure 21.

Next, an n-type Al_{0.2}Ga_{0.8}N electron supply layer 22 is formed on the GaN channel layer 20 at a temperature below the growth temperature T₁° C. as a first compound semiconductor layer. The n-Al_{0.2}Ga_{0.8}N electron supply layer 22, which has a thickness between 10 nm and 20 nm, is formed by crystal growth, by the addition of silicon (Si), which is an n-type impurity, at a concentration of 5×10¹⁸ cm⁻³. A two-dimensional electron gas 23 is generated at the interface between the GaN channel layer 20 and the n-Al_{0.2}Ga_{0.8}N electron supply layer 22 due to a difference in band gaps (FIG. 1D). Since the crystal growth conditions of the Al_{0.2}Ga_{0.8}N electron supply layer 22 are satisfied by the optimum conditions of crystal growth for the GaN channel layer 20, which are already set, no further optimization is necessary.

A second compound semiconductor layer, the constituent elements of which differ from the Al_{0.2}Ga_{0.8}N electron supply layer 22, is now formed. More specifically, an n-GaN layer 24 with a thickness between 10 nm and 20 nm is formed on the n-Al_{0.2}Ga_{0.8}N electron supply layer 22 by crystal growth, by the addition of silicon, which is an n-type impurity, with a concentration of 5×10¹⁸ cm⁻³, to obtain a multilayer structure 40 (FIG. 2A). During the formation of the n-GaN layer 24, its constituent atoms repeatedly evaporate from and are redeposited on the n-GaN surface. The first and second compound semiconductor layers 22 and 24 constitute a compound semiconductor multilayer 25.

The multilayer structure 40 is now cooled to a temperature between 20° C. and 100° C. (temperatures in this range will be denoted T₂° C. below). Temperature T₂° C. is not necessarily limited to the range between 20° C. and 100° C., but may be any temperature at which degradation of the n-GaN layer 24 at the surface of the multilayer structure 40 does not occur and evaporation (re-evaporation) of the constituent atoms of the n-GaN layer 24 from the surface of the n-GaN layer 24 stops after evaporation deposition. A temperature below the growth temperature of the low-temperature buffer layer may be used, for example.

Next a pair of stripe-shaped main electrodes such as a source electrode and a drain electrode are formed on the n-GaN layer 24 (the second compound semiconductor layer), spaced apart by a certain distance (FIG. 2B). These electrodes will be separately coupled through the n-GaN layer 24 to the underlying first compound semiconductor layer 22 when the n-GaN layer 24 becomes a contact layer 32 later on.

For example, a resist pattern (not shown) exposing two stripe-shaped areas of the n-GaN layer 24 having a certain width and separated by a certain distance is formed by photolithography. (This process will be simply referred to as ‘forming a resist pattern’ below.) The resist pattern then serves as a mask while, for example, titanium (Ti), aluminum (Al), and gold (Au) are successively deposited by an evaporation deposition process to form a metal multilayer film including, for example, a titanium layer 15 nm thick, an aluminum layer 200 nm thick, and a gold layer 600 nm thick. The resist pattern and the metal deposited thereon are then removed by a lift-off technique, leaving a stripe-shaped multilayer metal source electrode 26 and a stripe-shaped multilayer metal drain electrode 28 on the n-GaN layer 24.

Next, the part of the second compound semiconductor layer 24 disposed between the source electrode 26 and drain electrode 28 is etched to expose the underlying first compound semiconductor layer 22. The part of the n-GaN layer 24 on which the source electrode 26 is formed, and the part of the n-GaN layer 24 on which the drain electrode 28 is formed are left intact. The surface of the first compound semiconductor layer 22 is exposed between these parts.

More specifically, a photoresist 30 is formed with a resist pattern that exposes a stripe-shaped area of the n-GaN layer 24 of a certain width between the source electrode 26 and the drain electrode 28, and this resist pattern serves as a mask while the exposed part of the n-GaN layer 24 is removed by dry etching to expose the surface of the n-type Al_{0.2}Ga_{0.8}N electron supply layer 22. The dry etching process is carried out at room temperature by ICP-RIE, for example, using a chlorine-based etching gas such as boron chloride (BCl₃) or the like, which causes comparatively little specimen damage. By exposing the surface of the n-Al_{0.2}Ga_{0.8}N electron supply layer 22, this ICP-RIE etching process divides the n-GaN second compound semiconductor layer 24 into a pair of contact layers 32 (FIG. 2C).

The invention is not limited to the use of ICP-RIE; the n-GaN layer 24 can be etched by other dry etching processes, such as the electron cyclotron resonance (ECR) etching process.

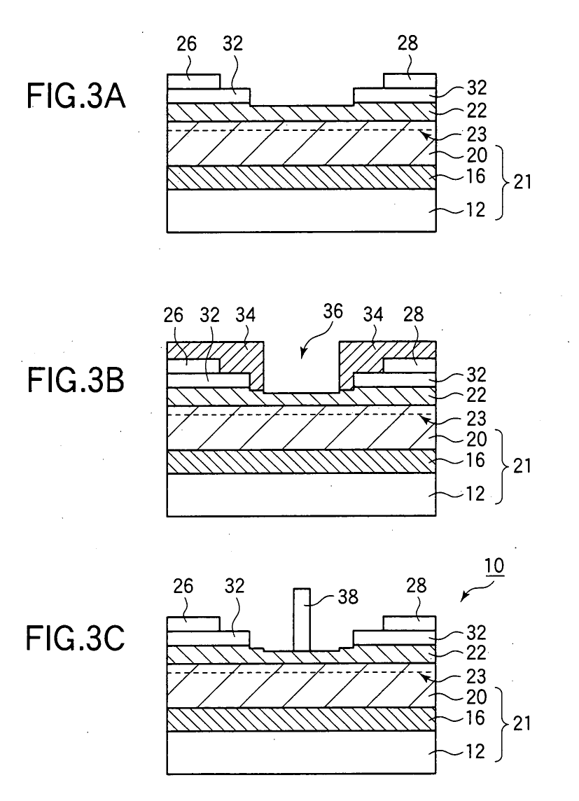

The resist pattern is then removed, and the partially exposed n-Al_{0.2}Ga_{0.8}N electron supply layer 22 is annealed in a nitrogen atmosphere, at a temperature of at least 400° C., for a period of twenty to eighty minutes. This annealing process removes the unnecessary etching gas species adsorbed by the exposed surface of the n-Al_{0.2}Ga_{0.8}N electron supply layer 22 (FIG. 3A).

Absorption of the etching gas species in the surface of the Al_{0.2}Ga_{0.8}N electron supply layer 22 can be measured by x-ray photoelectron spectroscopy (XPS), a technique that is capable of detecting etching gas species that appear to have been adsorbed in the surface during ICP-RIE. In the XPS spectrum, a chlorine peak appears if a chlorine-based etching gas (such as Cl₂+H₂+CH₄) is used, for example; boron and chlorine peaks appear if BCl₃ gas is used.

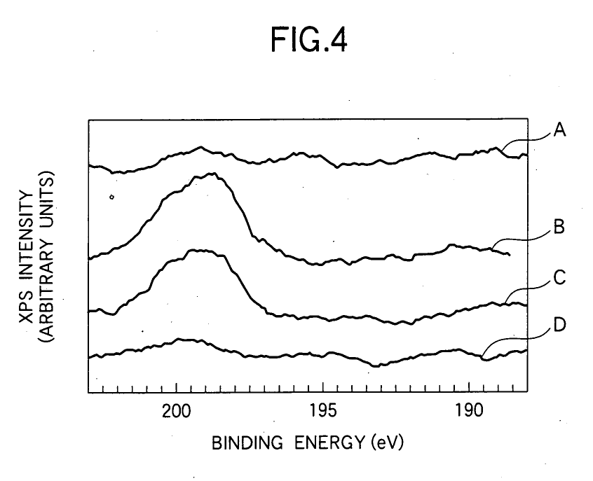

FIG. 4 shows the results of XPS measurements made during the steps in which the n-GaN layer 24 is etched by ICP-RIE (using BCl₃ as an etching gas) so that part of the surface of the Al_{0.2}Ga_{0.8}N electron supply layer 22 is exposed, and the Al_{0.2}Ga_{0.8}N electron supply layer 22 is annealed. The horizontal axis in FIG. 4 indicates binding energy in electron volts (eV);. the vertical axis indicates the measured x-ray photoelectron intensity in arbitrary units.

Curve A indicates the spectrum of the surface of the n-GaN layer 24 before ICP-RIE. Noise level variations are visible, but there are no distinctive peaks. Curve B indicates the spectrum of the surface of the n-GaN layer 24 at the stage at which half of the thickness of the n-GaN layer 24 has been etched by ICP-RIE. A distinctive peak deriving from the chlorine 2p orbitals appears near a binding energy of 199 eV, indicating that the etching gas species is being adsorbed on the surface of the n-GaN layer 24 during the ICP-RIE etching process. Curve C indicates the spectrum of the n-AlGaN layer surface when the n-GaN layer 24 has been removed by ICP-RIE and the surface of the n-type Al_{0.2}Ga_{0.8}N electron supply layer 22 is completely exposed. A distinctive chlorine peak appears near a binding energy of 199 eV as in spectrum B, indicating that the etching gas species has also been adsorbed on the exposed surface of the n-type Al_{0.2}Ga_{0.8}N electron supply layer 22. Curve D indicates the spectrum of the surface of the n-type Al_{0.2}Ga_{0.8}N electron supply layer 22 after the n-AlGaN surface has been exposed by ICP-RIE and the layer has been annealed. The chlorine peak that appears near a binding energy of 199 eV in spectra B and C has vanished, and only a varying noise level is visible, as in spectrum A, indicating that the etching gas species adsorbed on the surface of the n-type Al_{0.2}Ga_{0.8}N electron supply layer 22 have been removed by annealing.

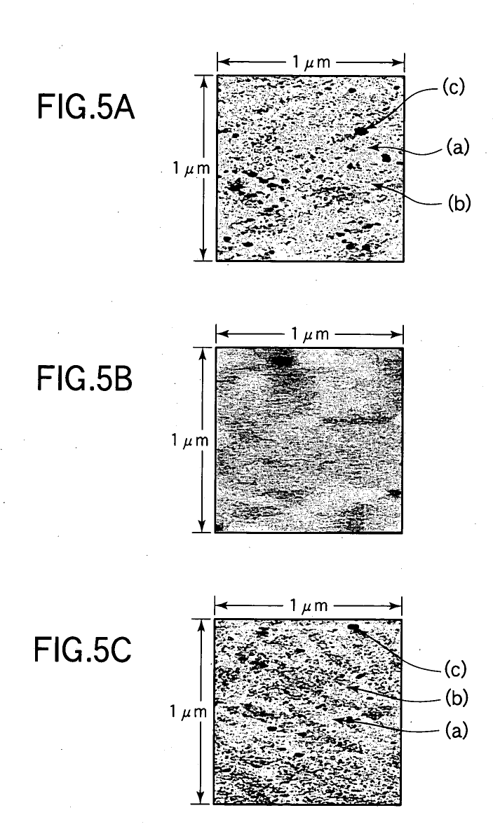

Next, the surface structure of the n-type Al_{0.2}Ga_{0.8}N electron supply layer 22 exposed by dry etching using ICP-RIE RIE (with a BCl₃ etching gas) was investigated with an atomic force microscope (AFM). FIGS. 5A, 5B, and 5C are AFM images of one-micrometer squares in the exposed n-type Al_{0.2}Ga_{0.8}N electron supply layer 22, scanned with a scanning rate of about 1.0 Hz. The white areas (a) are the reference plane (the surface in contact with the AFM probe); the black areas (c) are pits having a depth of about 5 nm from the reference plane; the gray areas (b) are pits of lesser depth.

FIG. 5A shows an AFM image of the surface immediately after ICP-RIE dry etching (with a BCl₃ etching gas) Although pits up to 5 nm deep and steps 0.4 nm to 0.5 nm high are visible, there are no large pits as deep as 10 nm or large steps as high as 10 nm, for example, indicating that the surface is flat.

FIG. 5B shows an AFM image of the surface after annealing for five minutes. This image is indistinct, compared with the image taken before annealing (FIG. 5A). Near the surface, there is an unstable part (which will also be referred to as a damaged layer) because the bonds between atoms are weakened due to damage from the ICP-RIE dry etching process. The reason for the indistinctness of this image is thought to be that the damaged layer is about to be desorbed.

FIG. 5C shows an AFM image of the surface after annealing for 20 minutes. A clear image is visible because all of the damaged layer which appeared in FIG. 5B has been desorbed. Although there are pits up to 5 nm deep and steps 0.4 nm to 0.5 nm high, a flat surface is shown, substantially the same as in FIG. 5A, indicating that after annealing, the exposed n-type Al_{0.2}Ga_{0.8}N electron supply layer 22 has a flat surface structure.

The results of XPS and AFM observations indicate that the etching gas species adsorbed on the surface of the n-type Al_{0.2}Ga_{0.8}N electron supply layer 22 and the damaged layer are removed by annealing.

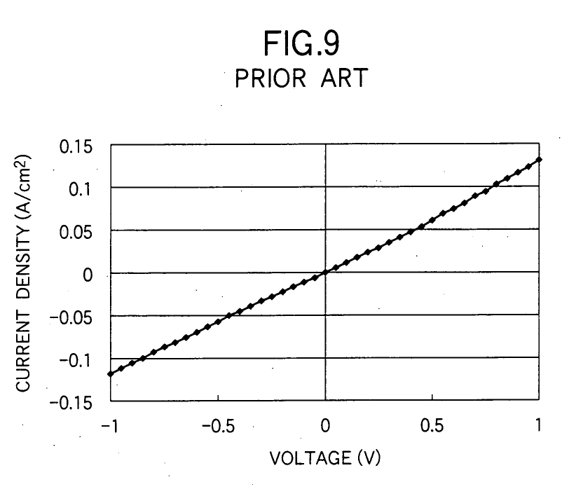

After annealing, the gate electrode is formed by evaporation deposition of nickel (Ni), for example, on the surface of the n-type Al_{0.2}Ga_{0.8}N electron supply layer 22, and the recessed HEMT 50 is fabricated by conventional methods. The I-V characteristic of the gate electrode formed as described above, however, displays an ohmic characteristic similar to the one shown in FIG. 9, instead of the desired Schottky characteristic. Therefore, in the present invention, the surface of the n-type Al_{0.2}Ga_{0.8}N electron supply layer 22 is treated with nitrogen plasma after the n-type Al_{0.2}Ga_{0.8}N electron supply layer 22 is annealed.

For example, a resist pattern exposing at least a stripe-shaped part of a certain width on the exposed surface of the n-type Al_{0.2}Ga_{0.8}N electron supply layer 22 is formed with a photoresist 34. The width should be wider than the width of the area on which the gate electrode will be formed later (FIG. 3B).

The exposed surface of the n-type Al_{0.2}Ga_{0.8}N electron supply layer 22 is then treated with nitrogen plasma with the resist pattern 34 as a mask. In the first embodiment, the nitrogen plasma surface treatment is carried out as a dry etching process performed with ICP-RIE equipment. Exemplary etching conditions are a nitrogen flow rate of ten standard cubic centimeters per minute (10 sccm), a nitrogen plasma processing pressure of 2.5 mTorr, a substrate temperature of 40° C., an ICP output of fifty watts (50 W), a radio frequency (RF) power of 30 W, a direct current (DC) bias of about eighty volts (80 V), and a processing time of 30 seconds, but these processing conditions may be modified. An adequate etching time is a time such that the surface of the n-type Al_{0.2}Ga_{0.8}N electron supply layer 22 is etched to the extent of about one unit cell. The crystal lattice unit in a GaN layer and an AlGaN layer generally has a hexagonal prism shape. In the first embodiment, a c-axis-oriented sapphire substrate is used as the basis of the multilayer structure 40, so it can be assumed that the n-GaN layer 24 and the n-type Al_{0.2}Ga_{0.8}N electron supply layer 22 maintain the c-axis-orientation. Therefore, the length of one unit cell (one lattice unit) is the length in the height direction (perpendicular to the substrate surface) from the hexagonal undersurface to the hexagonal top surface of the hexagonal prism. For example, since the lattice constant in the c-axis direction (the height direction from the hexagonal undersurface to the hexagonal top surface of the hexagonal prism in a GaN layer is 0.52 nm, it suffices for the layer to be etched to a depth of up to about 0.6 nm to 0.7 nm.

In this example, since the nitrogen plasma surface treatment is carried out by the ICP-RIE method, the treatment time can be defined in terms of etching depth. Adequate recovery from nitrogen vacancy damage can be obtained without etching the damaged surface, however; the nitrogen plasma surface treatment can be carried out simply by exposing the damaged surface to nitrogen plasma. Available methods of generating nitrogen plasma for non-etching surface treatment include the inductively coupled plasma (ICP) method, the capacitively coupled plasma (CCP) method, the electron cyclotron resonance (ECR) method, the helicon wave plasma method, and the surface wave plasma (SWP) method. The treatment time should be long enough for adequate recovery from the nitrogen vacancy damage by exposure of the nitrogen vacancies to the nitrogen plasma.

Next, a gate electrode 38 is formed by conventional methods in the prospective gate electrode formation region 36 that was treated with nitrogen plasma. For example, a resist pattern (not shown) exposing at least a stripe-shaped part of the n-type Al_{0.2}Ga_{0.8}N electron supply layer 22 having a certain width may be formed; then a gate electrode is formed on the exposed stripe by depositing, for example, nickel (Ni) and gold (Au) by an evaporation deposition process to form a nickel layer 50 nm thick and a gold layer 700 nm thick. The resist pattern and the metal deposited thereon are then removed by a lift-off technique, leaving a stripe-shaped nickel gate electrode 38 on the n-type Al_{0.2}Ga_{0.8}N electron supply layer 22, and completing the fabrication of the recessed HEMT 10 (FIG. 3C).

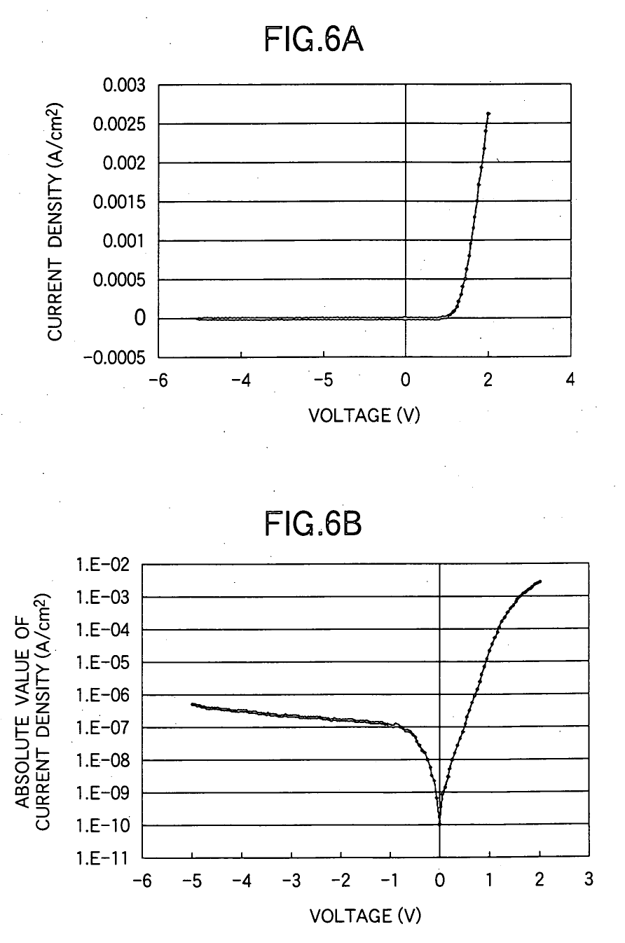

The gate-to-drain (or gate-to-source) I-V characteristic of the recessed HEMT 10 fabricated in the first embodiment is shown in FIGS. 6A and 6B. In FIG. 6A, the horizontal axis indicates voltage in volts (V), and the vertical axis indicates current density in amperes per square centimeter (A/cm²). When the voltage is negative, the current density takes on a very small value near zero; when the voltage is positive (especially, when it is at least 1 V), the current density increases rapidly, indicating a good Schottky characteristic. In FIG. 6B, to show variations in the area of small values of current density, the vertical axis indicates the absolute value of the current density on a logarithmic scale, for the same measurement data as in FIG. 6A. The absolute value is used so that the logarithm can be taken. As the voltage value increases from −5 V to 0 V, the absolute value of the current density approaches zero; when the voltage value becomes positive, the absolute value of the current density increases rapidly, again indicating a good Schottky characteristic.

The reasons why a recessed HEMT 10 having a good Schottky characteristic is obtained by etching the n-type Al_{0.2}Ga_{0.8}N electron supply layer 22 with nitrogen plasma are thought to be as follows. During the ICP-RIE etching process, on the surface of the n-type Al_{0.2}Ga_{0.8}N electron supply layer 22, nitrogen vacancies are thought to be present at a level such that their presence cannot be detected in an AFM image. The reason why the I-V characteristic of the gate electrode on the recessed HEMT displays an ohmic characteristic is thought to be that the nitrogen vacancies are not decreased by annealing and the defects due to the nitrogen vacancies function as donor levels.

In the present invention, when the surface with nitrogen vacancies is etched to the extent of about one unit cell by etching the n-type Al_{0.2}Ga_{0.8}N electron supply layer 22 with nitrogen plasma, a recovery from the defects due to the nitrogen vacancies is made by supplying nitrogen to the nitrogen vacancies, obtaining an n-type Al_{0.2}Ga_{0.8}N electron supply layer 22 having good electrical characteristics.

In the first embodiment, damage due to nitrogen vacancies in the surface of the first compound semiconductor layer 22 from dry etching can be eliminated or reduced. As a result, the surface structure of the first compound semiconductor layer 22 has good electrical characteristics, so a recessed HEMT 10 with a gate electrode having a good Schottky characteristic can be fabricated.

The Schottky I-V characteristic shown in FIGS. 6A and 6B was obtained from a recessed HEMT fabricated by the process described above, including nitrogen plasma surface treatment performed as a nitrogen plasma etching step. Similar Schottky characteristics are obtained when a recessed HEMT is fabricated by a process including nitrogen plasma surface treatment performed simply by exposure to nitrogen plasma, without etching.

### Second Embodiment

In the first embodiment, to form a gate electrode having a good Schottky characteristic, nitrogen vacancies in the surface of an n-AlGaN layer are removed by treatment with nitrogen plasma by using ICP-RIE equipment. If the ICP-RIE RIE equipment has already been used with a chlorine-based etching gas such as a BCl₃, however, chlorine-based etching gas species may be readsorbed by the surface of the n-AlGaN layer during the treatment with nitrogen plasma.

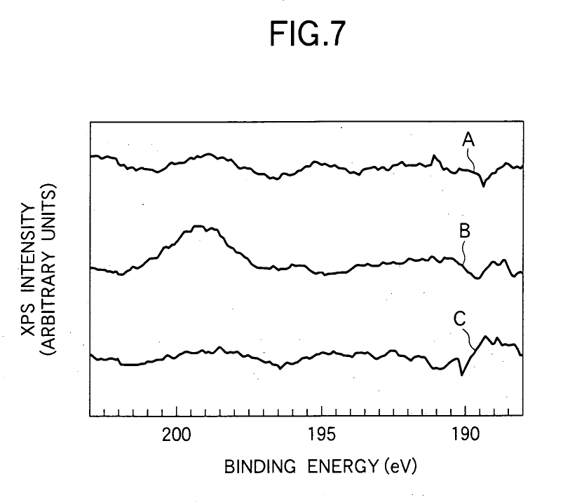

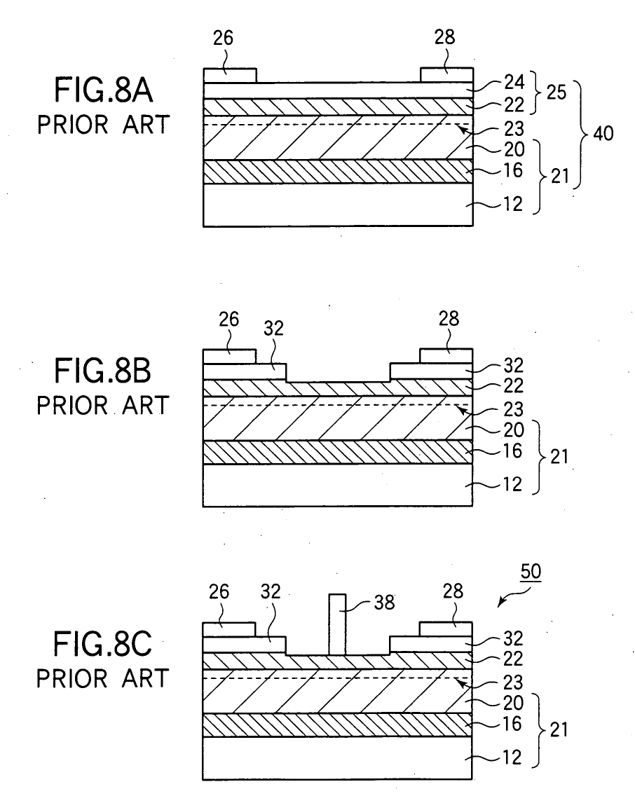

FIG. 7 shows the results of XPS measurements of the surface of an n-AlGaN layer made during a treatment process with nitrogen plasma using ICP-RIE equipment which had already been used with a BCl₃ gas. The horizontal axis indicates binding energy in electron volts (eV); the vertical axis indicates measured x-ray photoelectron intensity in arbitrary units.

Curve A indicates the XPS spectrum of the surface of the n-AlGaN layer immediately after the n-AlGaN layer has been annealed. The chlorine peak near a binding energy of 199 eV has vanished, indicating that the adsorbed chlorine has been removed. Curve B indicates the XPS spectrum of the surface of the n-AlGaN layer after the n-AlGaN layer has been treated with nitrogen plasma. A chlorine peak reappears near a binding energy of 199 eV, indicating that the etching gas species which remained present in the ICP-RIE equipment from earlier etching and was removed by annealing has been adsorbed again during the nitrogen plasma treatment process. An increase in chlorine-related peak intensities was also clearly recognizable in spectra (not shown) obtained with a quadrupole mass spectrometer (QMS) attached to the ICP-RIE equipment, indicating the presence of chlorine in the equipment.

It can be inferred that if the ICP-RIE equipment employed for nitrogen plasma treatment has already been used with a chlorine-based etching gas species such as BCl₃ or the like, the etching gas remaining in the equipment (on the sidewalls of the chamber, for example) may be adsorbed by the surface of the n-type Al_{0.2}Ga_{0.8}N electron supply layer 22 during the nitrogen plasma treatment process. If a gate electrode is formed on the surface of the n-AlGaN layer that has adsorbed an etching gas species as described above, the semiconductor device will not operate normally.

A pure water rinse is suitable for removing chlorine-based etching gas species and the like that have been adsorbed on the surface of the n-AlGaN layer during nitrogen plasma surface treatment. More specifically, the series of steps described in the first embodiment is performed to the end of nitrogen plasma treatment process, which may be carried out either as an etching process or simply by exposure to nitrogen plasma. If the nitrogen plasma treatment process is carried out by etching, using ICP-RIE equipment that was also used when the n-GaN layer 24 was etched with BCl₃, a chlorine peak appears near a binding energy of 199 eV in the XPS spectrum of the surface of the n-type Al_{0.2}Ga_{0.8}N electron supply layer 22.

Next, the surface of the n-type Al_{0.2}Ga_{0.8}N electron supply layer 22 is rinsed with pure water at room. temperature for twenty minutes.

In FIG. 7, curve C indicates the XPS spectrum of the surface of the n-AlGaN layer after the pure water rinse. The chlorine peak that appeared due to nitrogen plasma treatment has disappeared, and only a varying noise level is visible, indicating that the chlorine has been removed.

After the surface of the n-AlGaN layer has been rinsed with pure water, it is dried in a flow of nitrogen gas, for example; then a gate electrode 38 is formed on the surface of the n-AlGaN layer as in the first embodiment.

A recessed HEMT fabricated as described above provides the same effects as in the first embodiment, including a good Schottky characteristic. Accordingly, even when ICP-RIE equipment cannot be reserved for exclusive use in the nitrogen plasma treatment process, a surface structure having good electrical characteristics can be obtained in the first compound semiconductor layer if the surface is rinsed with pure water.

In both the first and second embodiments described above, the invented fabrication method reduces damage caused by dry etching, which produces unwanted nitrogen vacancies in the surface of a first of two compound semiconductor layers. By recovering from or reducing the nitrogen vacancy damage, the invented fabrication method gives the first compound semiconductor layer a surface structure having good electrical characteristics.

The invention is not restricted to the first and second embodiments described above.

For example, the semiconductor device to which the invention is applied need not be a recessed HEMT; the invention is applicable to any semiconductor device fabricated by a process in which part of the surface of a compound semiconductor layer including nitrogen is damaged by etching prior to the formation of a gate electrode on that part.

Although a sapphire substrate is used in the first and second embodiments, a silicon carbide (SiC) substrate or the like may be used instead. If a silicon carbide substrate is used, a suitable buffer layer can be formed from aluminum nitride (AlN).

When the invention is applied to an HEMT, the HEMT may have any substrate structure in which a two-dimensional electron gas can be obtained.

The first compound semiconductor layer in the first and second embodiments is not restricted to Al_{0.2}Ga_{0.8}N; any suitable AlₓGa₁₋ₓN compound (0 <×<1) may be used, as required by the purpose and design of the device.

Those skilled in the art will recognize that further variations are possible within the scope of the invention, which is defined in the appended claims.

What is claimed is:

1. A surface treatment method for a compound semiconductor layer, the compound semiconductor layer including nitrogen, the method including a nitrogen plasma treatment step to recover from damage due to nitrogen vacancies arising in a surface of the compound semiconductor layer.

2. The surface treatment method of claim 1, wherein the nitrogen plasma treatment step is performed by inductively coupled plasma reactive ion etching.

3. The surface treatment method of claim 1, wherein the nitrogen plasma treatment step is performed by non-etching exposure to nitrogen plasma.

4. The surface treatment method of claim 1, wherein the treated surface of the compound semiconductor layer is rinsed with pure water after the nitrogen plasma treatment step.

5. A surface treatment method for a compound semiconductor layer, the compound semiconductor layer being a compound semiconductor multilayer comprising a first compound semiconductor layer including nitrogen and a second compound semiconductor layer formed on and differing in composition from the first compound semiconductor layer, the method including:
removing part of the second compound semiconductor layer by dry etching to partially expose a surface of the first compound semiconductor layer; and
performing a nitrogen plasma treatment step to recover from damage due to nitrogen vacancies arising in the exposed surface of the first compound semiconductor layer.

6. The surface treatment method of claim 5, wherein the first compound semiconductor layer comprises aluminum gallium nitride (AlₓGa_{1-×}N, 0<×<1) and the second compound semiconductor layer comprises gallium nitride (GaN).

7. The surface treatment method of claim 5, wherein the nitrogen plasma treatment step is performed by inductively coupled plasma reactive ion etching.

8. The surface treatment method of claim 5, wherein the nitrogen plasma treatment step is performed by non-etching exposure to nitrogen plasma.

9. The surface treatment method of claim 5, wherein the treated surface of the first compound semiconductor layer is rinsed with pure water after the nitrogen plasma treatment step.

10. A method of fabrication of a semiconductor device, the method comprising:
forming a compound semiconductor multilayer on a substrate, the compound semiconductor multilayer having a first compound semiconductor layer including nitrogen and a second compound semiconductor layer formed on and differing in composition from the first compound semiconductor layer;
forming a first main electrode and a second main electrode on the second compound semiconductor layer, the first and second main electrodes being mutually separated by a certain distance;
removing an area of the second compound semiconductor layer between the first main electrode and the second main electrode by dry etching to expose a surface of the first compound semiconductor layer;
annealing the partially exposed first compound semiconductor layer;
treating at least part of the exposed surface area of the first compound semiconductor layer with nitrogen plasma; and
forming a gate electrode on said part of the exposed surface area of the first compound semiconductor layer.

11. The method of fabrication of a semiconductor device of claim 10, wherein the first compound semiconductor layer comprises aluminum gallium nitride (AlₓGa_{1-×}N, 0<×<1) and the second compound semiconductor layer comprises gallium nitride (GaN).

12. The method of fabrication of a semiconductor device of claim 10, wherein the treatment with nitrogen plasma is performed by inductively coupled plasma reactive ion etching.

13. The method of fabrication of a semiconductor device of claim 10, wherein the nitrogen plasma treatment step is performed by non-etching exposure to nitrogen plasma.

14. The method of fabrication of a semiconductor device of claim 10, further comprising rinsing the treated surface of the first compound semiconductor layer with pure water after the nitrogen plasma treatment step.

15. The method of fabrication of a semiconductor device of claim 10, wherein the semiconductor device is a high electron mobility transistor.
